(19) United States
(12) Patent Application Publication
(10) Pub. No.: US 2017/0144888 A1
(43) Pub. Date: May 25, 2017

(54) METHOD FOR GROWING GRAPHENE BY CHEMICAL VAPOR DEPOSITION

(71) Applicant: G-FORCE NANOTECHNOLOGY LTD., Kaohsiung City (TW)

(72) Inventors: Jen-Kuan Chiu, HSINCHU (TW); Chao-Hui Yeh, HSINCHU (TW); Po-Wen Chiu, HSINCHU (TW)

(21) Appl. No.: 15/072,374

(22) Filed: Mar. 17, 2016

Related U.S. Application Data
(60) Provisional application No. 62/258,553, filed on Nov. 23, 2015.

(51) Int. Cl. C01B 31/04; C23C 16/513; C23C 16/455

(52) U.S. Cl. CPC C01B 31/0453; C23C 16/45593; C23C 16/513

(57) ABSTRACT

A method for growing graphene by chemical vapor deposition is described. At least one substrate is loaded in a furnace. A reaction gas containing at least an oxygen-containing carbon source is introduced into the furnace. The reaction gas is heated and is UV-irradiated with a UV source, so that the carbon source is decomposed. A graphene film is deposited on a surface of the at least one substrate by the carbon atoms released by the decomposition of the carbon source.

### CROSS-REFERENCE TO RELATED APPLICATION

This application claims the priority benefit of U.S. provisional application Ser. No. 62/258,553, filed on Nov. 23, 2015. The entirety of the above-mentioned provisional patent application is hereby incorporated by reference herein and made a part of this specification.

### BACKGROUND OF THE INVENTION

Field of Invention

This invention relates to a method for growing graphene, and particularly relates to a method for growing graphene by chemical vapor deposition (CVD).

Description of Related Art

Graphene is a 2D structure including a single atomic layer of sp² carbon atoms arranged in a honeycomb lattice. The exotic properties of graphene, especially its high carrier mobility, hardness, thermal conductivity, current carrying capacity and extremely large surface-to-volume ratio, have prompted research interest into applications of graphene in the next generation of bio-medical, electronic and optoelectronics devices.

An approach to obtain graphene is chemical vapor deposition (CVD). CVD graphene has been successfully grown on various transition metals. In such a growth process, a carbon-containing gas is heated to a high temperature and catalyzed by the transition metal to be decomposed. Depending on the various catalytic effects of the transition metals on the hydrocarbon molecules and their corresponding carbon solubility, the decomposed carbon atoms cause different degrees of deposition, dissolution and precipitation on the surface of the transition metal substrate.

For copper foils, a typical metallic substrate for graphene growth, when the carbon atoms covering the metal surface form a continuous graphene film, this film provides a protective shield, thus the metal surface loses its capability to catalyze the decomposition of the subsequently introduced hydrocarbon molecules. This self-limiting growth mechanism restricts the graphene layers grown on the copper surface to a 90% monolayer coverage.

Moreover, to electrically isolate the graphene film, the metal substrate has to be removed by wet (acid) etching, and the graphene film is then transferred to an insulating substrate with the aid of a thin polymer scaffold. However, the graphene film is often damaged by the strong acid in the etching process, residual metal particles inevitably remain on the graphene surface to scatter electrons and hence reduce electron mobility, and the thin polymer scaffold, which is usually composed of long-chain hydrocarbon molecules, is difficult to completely remove using any known organic solvent.

### SUMMARY OF THE INVENTION

This invention provides a novel method that allows direct growth of low-defect graphene films on a surface of a substrate by chemical vapor deposition, in particular on an insulating surface.

The method for growing graphene by CVD of this invention is described below. At least one substrate is loaded in a furnace. A reaction gas containing an oxygen-containing carbon source is introduced into the furnace. The reaction gas is heated and is UV-irradiated with a UV source, so that the oxygen-containing carbon source is decomposed. A graphene film is deposited on a surface of the at least one substrate by the carbon atoms released by the decomposition of the carbon source.

The at least one substrate may comprise at least one insulating substrate or at least one metallic substrate, in particular at least one insulating surface

In an embodiment of this invention, the above method further includes using a plasma source to assist the decomposition of the carbon source.

In another embodiment of this invention, the above method further includes providing a metal vapor as a catalyst into the furnace. The metal vapor may be provided from a solid metal that includes copper, nickel, zinc, or a combination thereof and is put in the furnace, or alternatively from an organometallic compound provided to the furnace.

The reaction gas may further contain a carbon-free oxygen-containing compound, such as H₂O. The reaction gas may further contain a hydrogen gas, and an inert gas as a diluting gas.

Since the carbon source is decomposed by UV-irradiation at high temperature but not by a metal surface, a nearly 100% monolayer coverage can be achieved, and wet (acid) etching for a metal substrate and a polymer scaffold-aid transfer of the graphene film can be avoided preventing the above drawbacks caused by the wet (acid) etching and the polymer scaffold. Through a prolonged control over the growth time, a multilayer graphene film can be grown on a surface of a substrate, in particular on a surface of an insulating surface.

In order to make the aforementioned and other objects, features and advantages of this invention comprehensible, a preferred embodiment accompanied with figures is described in detail below.

### BRIEF DESCRIPTION OF THE DRAWINGS

FIG. 1 illustrates an apparatus for a method for growing graphene by chemical vapor deposition according to a first embodiment of this invention.

FIG. 2 illustrates an apparatus for a method for growing graphene by chemical vapor deposition according to a second embodiment of this invention.

FIG. 3 illustrates an apparatus for a method for growing graphene by chemical vapor deposition according to a third embodiment of this invention.

FIG. 4A shows the Raman spectrum of monolayer graphene grown on a sapphire substrate in Example 1 of this invention.

FIG. 4B shows the X-ray photoelectron spectroscopic spectrum of the monolayer graphene grown on the sapphire substrate in Example 1 of this invention.

FIG. 5 shows a cross-sectional electron microscopic image of the monolayer graphene grown directly on the sapphire substrate in Example 1 of this invention.

FIG. 6A shows a cross-sectional electron microscopic image of the multilayer graphene grown directly on a silicon nitride substrate in Example 2 of this invention.

FIG. 6B shows a cross-sectional electron microscopic image of the multilayer graphene grown directly on a silicon oxide substrate in Example 3 of this invention.

### DESCRIPTION OF EMBODIMENTS

This invention will be further explained with the following embodiments and the accompanying drawings, which are not intended to restrict the scope of this invention. For example, although the UV light for decomposing the carbon source begins acting on the reaction gas in a pipe and is also introduced in the furnace through the pipe in the embodiments, the UV light may alternatively be introduced in the furnace and act on the reaction gas therein through a window formed on the furnace. More specifically, the UV source may be located near the upstream of the reaction gas flow, and the UV light may irradiate in a direction substantially parallel to the planar direction of the at least one substrate through a transparent window into the interior space of the furnace.

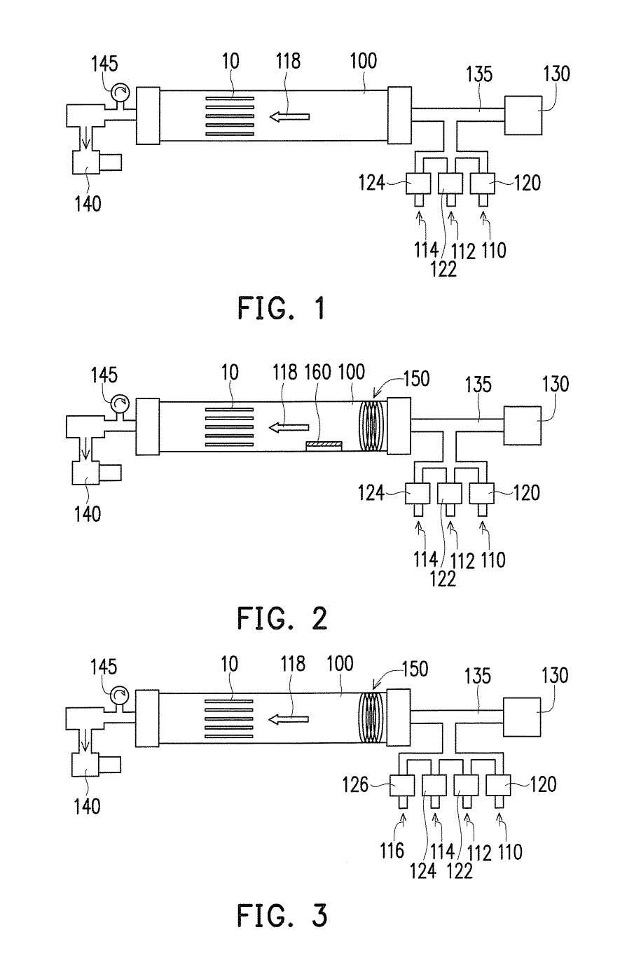

FIG. 1 illustrates an apparatus for a method for growing graphene by chemical vapor deposition according to the first embodiment of this invention.

Referring to FIG. 1, at least one substrate 10 is loaded in a furnace 100. The substrate 10 may be a wafer, which is loaded while being held in a wafer holder. The surface of the substrate 10 may be insulating or metallic. The insulating surface may include a material selected from the group consisting of silicon, germanium, silicon oxide, silicon nitride, silicon carbide, quartz, sapphire, glass, and a combination thereof. The metallic surface may include a material selected from the group consisting of copper (Cu), nickel (Ni), ruthenium (Ru), cobalt (Co), and a combination thereof. The surface of the substrate 10 may have been treated with oxygen plasma or hydrogen plasma prior to being loaded in the furnace 100. The oxygen plasma may serve to remove organic substances from the surface of the substrate 10. The hydrogen plasma may serve to reduce the native oxide film on a metallic surface of the substrate 10 or to clean up carbon-containing polymer residues or dirt on the substrate 10. The surface of the substrate 10 may have been deposited with patterned carbon-containing seeds before being loaded in the furnace 100.

Then, a gas 110 containing carbon and oxygen is introduced into the furnace 100, usually together with a hydrogen gas 112 as a catalytic gas and an inert gas 114 as a diluting gas to form a reaction gas. The gas 110 essentially contains an oxygen-containing carbon source. The gas 110 may further contain a carbon-free oxygen-containing compound, such as H₂O, so as to facilitate the graphitization of carbon atoms on a surface of the insulating substrate 10. The flow rates of the gas 110, the hydrogen gas 112 and the inert gas 114 are measured with three flow meters 120, 122 and 124, respectively. The gas 110, the hydrogen gas 112 and the inert gas 114 may be mixed in a pipe 135 before being injected into the furnace 100. A UV source 130 is arranged at an end of the pipe 135 in this embodiment, in a manner that the UV light emitted therefrom can be introduced in the pipe 135 and into the furnace 100 through the pipe 135.

While the reaction gas is introduced into the furnace 100, the pressure in the furnace 100 is reduced to a predetermined value by a vacuum pump 140, the furnace 100 is heated to a predetermined temperature, and UV light is provided by the UV source 130 to irradiate the reaction gas in the pipe 135 and the furnace 100. With the effects of the UV light and heat, the oxygen-containing carbon source contained in the reaction gas is decomposed, and the carbon atoms released by the decomposition deposit on the surface of each substrate 10 to form a graphene film thereon. The deposited graphene film may comprise monolayer graphene or multilayer graphene, depending on the process condition and reaction time.

The oxygen-containing carbon source may be selected from the group consisting of carbon monoxide, carbon dioxide, a ketone, an ether, an ester, an alcohol, an aldehyde, a phenol, an organic acid, and a combination thereof. The oxygen contained in carbon source has an effect of providing a reaction pathway with a reduced activation energy, through which carbon atoms can be graphitized on a surface of the insulating substrate. The inert gas 114 may be selected from argon and helium. Depending on the size of reaction chamber, the flow rate of the gas 110 containing carbon and oxygen may range from 5 sccm to 600 sccm, the flow rate of the hydrogen gas 112 may range from 5 sccm to 200 sccm, and the flow rate of the inert gas 114 may range from 60 sccm to 800 sccm. The pressure in the furnace 100 is measured by the vacuum gauge 145, and may be reduced to tens of torr. The furnace 100 may be heated to a temperature within the range of 600° C. to 1100° C. The UV light provided by the UV source 130 may have wavelength ranging from 160 nm to 400 mm.

In addition, when a plurality of substrates 10 comprising a plurality of wafers is loaded in the furnace 100, the wafers are preferably arranged parallel with each other and substantially parallel to the UV-irradiation direction 118 of the UV source 130. The hydrogen gas 112 and the inert gas 114 may also be supplied in the temperature rise stage prior to the deposition, so as to clean up the surface where graphene will be deposited uniformly. The flow rate of the hydrogen gas 112 in the temperature rise stage may range from 50 sccm to 600 sccm. The flow rate of the inert gas 114 in the temperature rise stage may range from 60 seem to 800 sccm.

Although in the above embodiment the carbon source is decomposed by UV light and heat only, at least one of a plasma source and a metal vapor may be further provided to assist the decomposition of the carbon source 110.

One of such modified embodiments is illustrated in FIG. 2 as the second embodiment of this invention, wherein a plasma source 150 is attached to the furnace 100 for inducing plasma in the reaction gas contained in the furnace 100, and a solid metal 160 is put in the furnace 100 for generating a metal vapor capable of catalyzing the decomposition of the carbon source 110. The solid metal 160 may include copper, nickel, zinc and a combination thereof. It is also possible that only one of the plasma source 150 and the solid metal 160 is provided.

In this second embodiment, in case the solid metal 160 is provided, a period in which only the hydrogen gas 112 and the inert gas 114 are provided may be inserted between the temperature rise stage and the deposition stage, allowing for the reduction reaction of the surface oxide of the solid metal 160. With the aid of the plasma source 150 and/or the catalytic metal vapor generated from the solid metal 160, the required temperature of the furnace 100 may be lowered, possibly to a value within the range of 400° C. to 1100° C.

Another one of the aforementioned modified embodiments is illustrated in FIG. 3 as the third embodiment of this invention, wherein the source of the metal vapor is an organometallic compound 116 being introduced into the furnace 100, instead of a solid metal 160 put in the furnace 100. The organometallic compound 116 can be decomposed by the high temperature in the furnace 100 to form a metal vapor capable of catalyzing the decomposition of the carbon source. The organometallic compound 116 may be introduced after being mixed with the gas 110, the hydrogen gas 112 and the inert gas 114, as shown in FIG. 3, while the flow rate thereof is measured with a flow meter 126. The organometallic compound 116 may comprise a metal selected from the group consisting of copper, nickel, platinum, and ruthenium.

In the above embodiments, since the carbon source is decomposed by UV light (and plasma and/or catalysis of a metal vapor) at high temperature but not by a metal surface, a nearly 100% monolayer coverage can be achieved, and wet (acid) etching for a metal substrate and a polymer scaffold-aid transfer of the graphene film can be avoided preventing the above drawbacks caused by the wet (acid) etching and the polymer scaffold.

In order to further explain this invention, Examples 1 to 3 are provided below, which are however not intended to restrict the scope of this invention.

In Example 1, monolayer graphene was grown directly on a sapphire substrate at 1000° C., using an apparatus as illustrated in FIG. 3. The deposition setting particularly includes a UV source providing continuous wavelengths ranging from 160 rim to 400 run. The UV source was located near the upstream of the reaction gas flow, and the UV light irradiated in a direction substantially parallel to the planar direction of the substrates through a transparent window into the interior space of the reaction chamber. Ethyl methyl ether was used as the oxygen-containing carbon source, with a constant flow rate of 30 sccm throughout the growth stage. Hydrogen gas was introduced as a catalytic gas with a flow rate of 120 sccm. Argon acted as a diluent gas with a flow rate of 200 sccm.

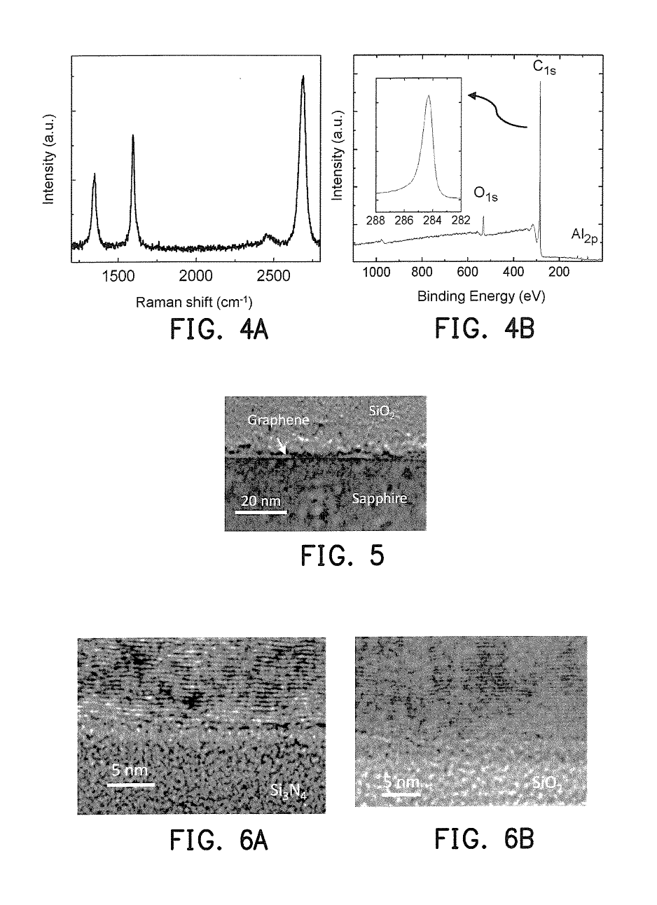

The Raman spectrum of the obtained monolayer graphene is shown in FIG. 4A, the X-ray photoelectron spectroscopic spectrum of the same is shown in FIG. 4B, and a cross-sectional electron microscopic image of the monolayer graphene being grown directly on the sapphire substrate is shown in FIG. 5.

It is clear from FIG. 4A that the narrow full width at half maximum of the G and 2D peaks indicate a high crystallinity of the resulting graphene layer. FIG. 4B shows that there was no traceable amount of metal residue found in the graphene film grown directly on the insulating substrate. It is clear from FIG. 5 that the resulting graphene layer is conformal to the substrate surface.

In Examples 2 and 3, multilayer graphene was grown directly on a silicon nitride substrate and a silicon oxide substrate, respectively, using the same apparatus as

### EXAMPLE 1

The deposition setting includes a UV light source providing continuous wavelengths ranging from 160 nm to 400 nm. The UV source was located near the upstream of the reaction gas flow, and the UV light irradiated in a direction substantially parallel to the planar direction of the substrates through a transparent window into the interior space of the reaction chamber. Ethyl methyl ether was used as the oxygen-containing carbon source, with a constant flow rate of 60 sccm throughout the growth stage. Hydrogen gas was introduced as a catalytic gas with a flow rate of 120 sccm. Argon acted as a diluent gas with a flow rate of 200 sccm. The plasma was ignited shortly before the growth starts and stayed on during the growth period.

A cross-sectional electron microscopic image of the multilayer graphene being grown directly on the silicon nitride substrate in Example 2 is shown in FIG. 6A. A cross-sectional electron microscopic image of the multilayer graphene being grown directly on the silicon oxide substrate in Example 3 is shown in FIG. 6B.

It is clear from FIG. 6A and FIG. 6B that graphene can be grown and stacked layer by layer on the insulating substrates. The multilayer stack obtained using this disclosed technique occurs parallel to the substrate surface, unlike graphene petals and other non-parallel graphene layers reported in the prior arts.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A method for growing graphene by chemical vapor deposition, comprising:
loading at least one insulating substrate in a furnace;
introducing a reaction gas containing an oxygen-containing carbon source into the furnace;
heating the reaction gas and UV-irradiating the reaction gas with a UV source, so that the oxygen-containing carbon source is decomposed; and
depositing a graphene film on a surface of the at least one insulating substrate.

2. The method of claim 1, further comprising using a plasma source to assist the decomposition of the oxygen-containing carbon source.

3. The method of claim 1, further comprising providing a metal vapor as a catalyst into the furnace.

4. The method of claim 3, wherein the metal vapor is provided from a solid metal that includes copper, nickel, zinc, or a combination thereof and is put in the furnace.

5. The method of claim 3, wherein the metal vapor is provided from an organometallic compound provided to the furnace.

6. The method of claim 5, wherein the organometallic compound comprises a metal selected from the group consisting of copper, nickel, platinum, and ruthenium..

7. The method of claim 1, wherein the surface of the at least one insulating substrate comprises a material selected from the group consisting of silicon, germanium, silicon oxide, silicon nitride, silicon carbide, quartz, sapphire, glass, and a combination thereof.

8. The method of claim 1, wherein the oxygen-containing carbon source is selected from the group consisting of carbon monoxide, carbon dioxide, a ketone, an ether, an ester, an alcohol, an aldehyde, a phenol, an organic acid, and a combination thereof.

9. The method of claim 1, wherein the reaction gas further comprises a carbon-free oxygen-containing compound.

10. The method of claim 9, wherein the carbon-free oxygen-containing compound comprises H₂O.

11. The method of claim 1, wherein the reaction gas further comprises a hydrogen gas and an inert gas.

12. The method of claim 1, wherein a plurality of insulating substrates comprising a plurality of wafers is loaded in the furnace, and the wafers are arranged parallel with each other and substantially parallel to an UV-irradiation direction of the UV source.

13. The method of claim 1, wherein the reaction gas is heated to a temperature within a range of 400° C. to 1100° C.

14. The method of claim 1, wherein the UV source provides UV light having a wavelength ranging from 160 nm to 400 nm.

15. The method of claim 1, wherein the UV source is located near upstream of a flow of the reaction gas, and the UV light irradiates in a direction substantially parallel to a planar direction of the at least one insulating substrate through a transparent window into an interior space of the furnace.

16. The method of claim 1, wherein the deposited graphene film comprises monolayer graphene or multilayer graphene.

17. The method of claim 1, wherein the surface of the at least one insulating substrate has been treated with oxygen plasma or hydrogen plasma prior to the deposition of the graphene film.

18. The method of claim 1, wherein the surface of the at least one insulating substrate has been deposited with patterned carbon-containing seeds prior to the deposition of the graphene film.

19. A method for growing graphene by chemical vapor deposition, comprising:
loading at least one metallic substrate in a furnace;
introducing a reaction gas containing an oxygen-containing carbon source into the furnace;
heating the reaction gas and UV-irradiating the reaction gas with a UV source, so that the oxygen-containing carbon source is decomposed; and
depositing a graphene film on a surface of the at least one metallic substrate.

20. The method of claim 19, wherein the at least one metallic substrate comprises a material selected from the group consisting of copper (Cu), nickel (Ni), ruthenium (Ru), cobalt (Co), and a combination thereof.
